(19) United States
(12) Patent Application Publication
(10) Pub. No.: US 2025/0324804 A1
(43) Pub. Date: Oct. 16, 2025

(54) PHOTODETECTOR AND DISTANCE MEASUREMENT APPARATUS

(71) Applicant: SONY SEMICONDUCTOR SOLUTIONS CORPORATION, Kanagawa (JP)

(72) Inventor: Satoru YOSHIDA, Kanagawa (JP)

(21) Appl. No.: 18/868,826

(22) PCT Filed: May 19, 2023
(86) PCT No.: PCT/JP2023/018729

§ 371 Date: Nov. 25, 2024

(30) Foreign Application Priority Data
Jun. 1, 2022 (JP) 2022-089585

(51) Int. Cl. H10F 39/00; G01S 7/481; G01S 17/08

(52) U.S. Cl. CPC H10F 39/811; G01S 7/4816; G01S 17/08; H10F 39/8027; H10F 39/807; H10F 39/809

(57) ABSTRACT

A photodetector of an embodiment of the disclosure includes: a semiconductor substrate having opposed first and second surfaces and including a pixel array section including pixels in array in an in-plane direction; a light-receiving section provided inside the substrate for each pixel and generating carriers corresponding to a received light amount by photoelectric conversion; a multiplication section performing avalanche multiplication of the carriers generated in the light-receiving section and including, for each pixel, first and second electrically-conductive regions having different electrically-conductive types and stacked on the first surface side; a pixel separation section provided between the adjacent pixels to extend from the first surface to the second surface, and electrically separating the adjacent pixels; a first contact layer provided around each pixel along the pixel separation section on the first surface and electrically coupled to the light-receiving section; a second contact layer provided on the first surface and electrically coupled to the multiplication section; and connection wiring provided independently for each pixel and electrically coupling the first contact layer and one or more wiring layers provided on the first surface side and included in a multilayer wiring layer.

### TECHNICAL FIELD

The present disclosure relates to a photodetector using, for example, an avalanche photodiode, and a distance measurement apparatus.

### BACKGROUND ART

For example, PTL 1 discloses a photoelectric conversion device in which avalanche photodiodes are separated in two layers in a depth direction, and the layers are each provided with separation sections having different shapes in a plan view and electrically separating semiconductor regions of adjacent pixels from each other.

### CITATION LIST

### Patent Literature

PTL 1: Japanese Unexamined Patent Application Publication No. 2020-141122

### SUMMARY OF THE INVENTION

Incidentally, a photodetector is required to suppress crosstalk.

It is desirable to provide a photodetector and a distance measurement apparatus that make it possible to suppress crosstalk.

A photodetector according to an embodiment of the present disclosure includes: a semiconductor substrate having a first surface and a second surface opposed to each other and including a pixel array section in which a plurality of pixels is arranged in array in an in-plane direction; a light-receiving section provided inside the semiconductor substrate for each of the pixels and generating carriers corresponding to a received light amount by photoelectric conversion; a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section; a pixel separation section provided between the plurality of pixels adjacent to each other to extend from the first surface to the second surface of the semiconductor substrate, the pixel separation section electrically separating the plurality of adjacent pixels from each other; a first contact layer provided around each of the plurality of pixels along the pixel separation section on the first surface of the semiconductor substrate and being electrically coupled to the light-receiving section; a second contact layer provided on the first surface of the semiconductor substrate and being electrically coupled to the multiplication section; and connection wiring that, in a multilayer wiring layer including one or a plurality of wiring layers provided on the side of the first surface of the semiconductor substrate, electrically couples the first contact layer and the one or the plurality of wiring layers to each other, the connection wiring being provided independently for each of the plurality of pixels.

A distance measurement apparatus according to an embodiment of the present disclosure includes: an optical system; a photodetector; and a signal processing circuit that calculates a distance to a measurement target from an output signal of the photodetector, and includes, as the photodetector, the photodetector according to an embodiment of the present disclosure.

In the photodetector and the distance measurement apparatus according to the respective embodiments of the present disclosure, the connection wiring is provided independently for each of the plurality of pixels. The connection wiring electrically couples the first contact layer provided around each of the plurality of pixels along the pixel separation section on the first surface of the semiconductor substrate and the wiring layers in the multilayer wiring layer provided on the side of the first surface of the semiconductor substrate to each other. This reduces leaked light from adjacent pixels.

### BRIEF DESCRIPTION OF THE DRAWINGS

FIG. 1 is a schematic cross-sectional view of an example of a photodetector according to a first embodiment of the present disclosure.

(A) of FIG. 2 is a schematic plan view of the photodetector corresponding to a line I-I illustrated in FIG. 1, and (B) of FIG. 2 is a schematic plan view of the photodetector corresponding to a line II-II illustrated in FIG. 1.

FIG. 3 is a block diagram illustrating an example of a schematic configuration of the photodetector illustrated in FIG. 1.

FIG. 4 is an example of an equivalent circuit diagram of a unit pixel of the photodetector illustrated in FIG. 1.

FIG. 5 is a schematic cross-sectional view of another example of the photodetector according to an embodiment of the present disclosure.

FIG. 6 is a schematic plan view of a photodetector according to Modification Example 1 of the present disclosure.

FIG. 7 is a schematic plan view of a photodetector according to Modification Example 2 of the present disclosure.

FIG. 8 is a schematic plan view of a photodetector according to Modification Example 3 of the present disclosure.

FIG. 9 is a schematic plan view of a photodetector according to Modification Example 4 of the present disclosure.

FIG. 10 is a schematic plan view of a photodetector according to Modification Example 5 of the present disclosure.

FIG. 11 is a schematic plan view of a photodetector according to Modification Example 6 of the present disclosure.

FIG. 12 is a schematic cross-sectional view of an example of a photodetector according to a second embodiment of the present disclosure.

(A) of FIG. 13 is a schematic plan view of the photodetector corresponding to a line III-III illustrated in FIG. 12, and (B) of FIG. 13 is a schematic plan view of the photodetector corresponding to a line IV-IV illustrated in FIG. 12.

FIG. 14 is a schematic plan view of a photodetector according to Modification Example 7 of the present disclosure.

FIG. 15 is a schematic cross-sectional view of an example of a photodetector according to a third embodiment of the present disclosure.

(A) of FIG. 16 is a schematic plan view of the photodetector corresponding to a line V-V illustrated in FIG. 15, and (B) of FIG. 16 is a schematic plan view of the photodetector corresponding to a line VI-VI illustrated in FIG. 15.

FIG. 17 is a schematic cross-sectional view of an example of a photodetector according to a fourth embodiment of the present disclosure.

(A) of FIG. 18 is a schematic plan view of the photodetector corresponding to a line VII-VII illustrated in FIG. 17, and (B) of FIG. 18 is a schematic plan view of the photodetector corresponding to a line VIII-VIII illustrated in FIG. 17.

FIG. 19 is a functional block diagram illustrating an example of an electronic apparatus using the photodetector illustrated in FIG. 1 or other drawings.

FIG. 20 is a block diagram depicting an example of schematic configuration of a vehicle control system.

FIG. 21 is a diagram of assistance in explaining an example of installation positions of an outside-vehicle information detecting section and an imaging section.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. First Embodiment (A photodetector in which connection wiring between a light-receiving section and an anode is formed continuously along a pixel independently for each pixel)
   1-1. Configuration of Photodetector
   1-2. Workings and Effects
2. Modification Examples
   2-1. Modification Example 1 (Another example of planar layout of connection wiring)
   2-2. Modification Example 2 (Another example of planar layout of connection wiring)
   2-3. Modification Example 3 (Another example of planar layout of connection wiring)
   2-4. Modification Example 4 (Another example of planar layout of connection wiring)
   2-5. Modification Example 5 (Another example of planar layout of connection wiring)
   2-6. Modification Example 6 (Another example of planar layout of connection wiring)
3. Second embodiment (A photodetector in which connection wiring is formed in a lattice pattern and a pixel separation section is formed inside a pixel independently for each pixel)
4. Modification Example 7 (Another example of planar layout of connection wiring)
5. Third Embodiment (A photodetector in which connection wiring between a light-receiving section and an anode is provided to straddle pixels adjacent to each other in a row direction and a column direction except intersections of pixels adjacent to each other in an oblique direction)
6. Fourth Embodiment (A photodetector in which a pixel separation section reaches wiring in a multilayer wiring layer)
7. Application Example
8. Practical Application Examples

### 1. First Embodiment

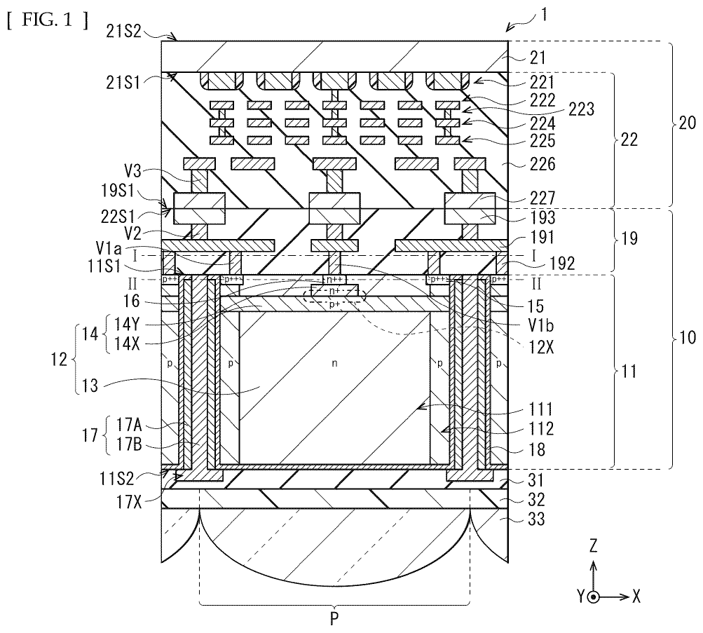

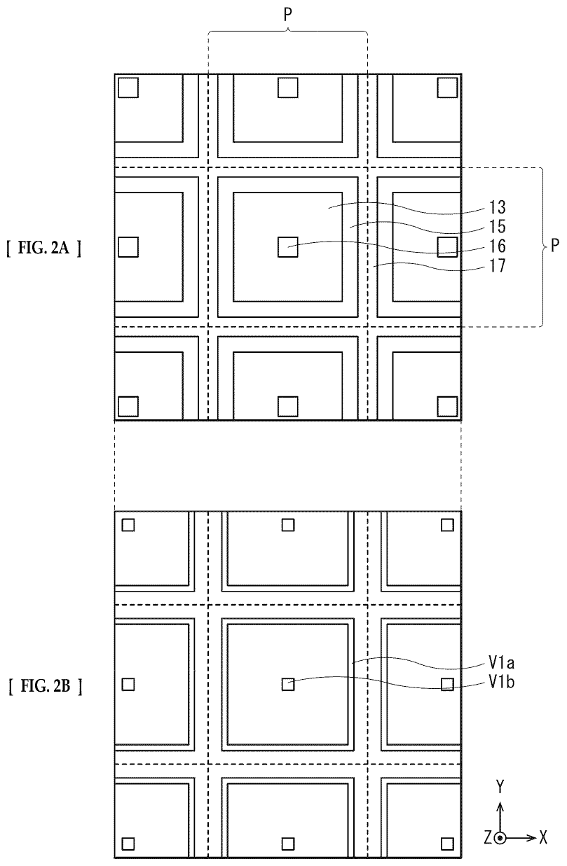

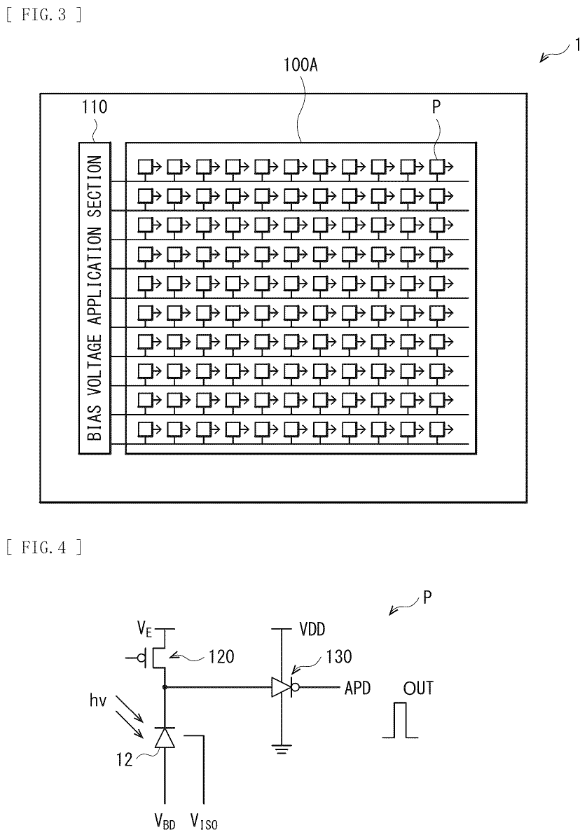

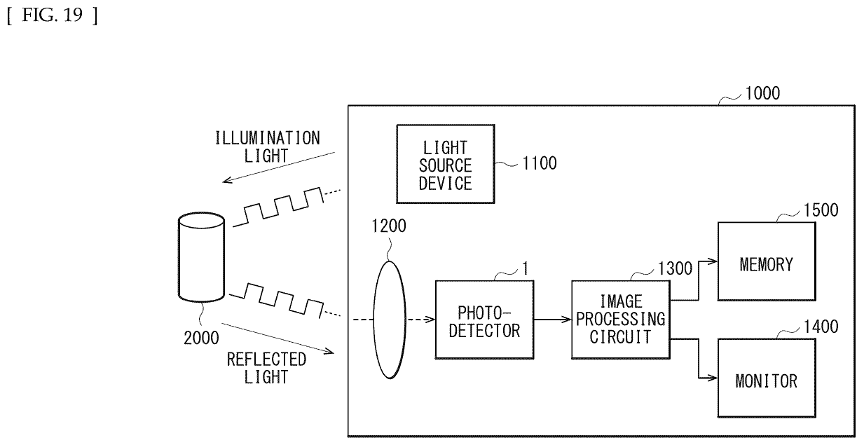

FIG. 1 schematically illustrates an example of a cross-sectional configuration of a photodetector (a photodetector 1) according to a first embodiment of the present disclosure. FIG. 2 schematically illustrates planar configurations of the photodetector 1 illustrated in FIG. 1 corresponding to a line I-I (A) and a line II-II (B). FIG. 3 is a block diagram illustrating a schematic configuration of the photodetector 1 illustrated in FIG. 1, and FIG. 4 illustrates an example of an equivalent circuit of a unit pixel P of the photodetector 1 illustrated in FIG. 1. The photodetector 1 is applied to, for example, a distance image sensor (a distance image apparatus 1000 described later; see FIG. 19) that performs distance measurement by a ToF (Time-of-Flight) method, an image sensor, or the like.

### (1-1. Configuration of Photodetector)

The photodetector 1 includes, for example, a pixel array section 100A in which a plurality of unit pixels P is arranged in a row direction and in a column direction. As illustrated in FIG. 3, the photodetector 1 includes a bias voltage application section 110 together with the pixel array section 100A. The bias voltage application section 110 applies a bias voltage to each of the unit pixels P in the pixel array section 100A. In the present embodiment, description is given of a case where electrons are read as signal charge.

As illustrated in FIG. 3, the unit pixel P includes a light-receiving element 12, a quenching resistance element 120 including a p-type MOSFET (Metal-Oxide-Semiconductor Field-Effect Transistor), and an inverter 130 including, for example, a complementary type MOSFET.

The light-receiving element 12 converts incident light into an electric signal by photoelectric conversion, and outputs the converted electric signal. The light-receiving element 12 collaterally converts the incident light (photon) into the electric signal by photoelectric conversion, and outputs a pulse corresponding to the incidence of the photon. The light-receiving element 12 is, for example, an SPAD (Single Photon Avalanche Diode) element. The SPAD element has, for example, a characteristic in which an avalanche multiplication region 12X (a depletion layer) is formed by a large negative voltage applied to a cathode, and electrons generated in response to the incidence of one photon cause avalanche multiplication and a large current flows. The light-receiving element 12 has, for example, an anode coupled to the bias voltage application section 110 and the cathode coupled to a source terminal of the quenching resistance element 120. A device voltage VB is applied from the bias voltage application section 110 to the anode of the light-receiving element 12.

The quenching resistance element 120 is coupled in series to the light-receiving element 12, and has the source terminal coupled to the cathode of the light-receiving element 12 and a drain terminal coupled to an unillustrated power supply. An excitation voltage V_{E} is applied from the power supply to the drain terminal of the quenching resistance element 120. When a voltage of electrons having been subjected to the avalanche multiplication by the light-receiving element 12 reaches a negative voltage V_{BD}, the quenching resistance element 120 performs quenching in which the electrons multiplied by the light-receiving element 12 are emitted to return the voltage to an initial voltage.

The inverter 130 has an input terminal coupled to the cathode of the light-receiving element 12 and to the source terminal of the quenching resistance element 120, and an output terminal coupled to an unillustrated subsequent arithmetic processing section. The inverter 130 outputs a light-receiving signal on the basis of the carriers (signal charge) multiplied by the light-receiving element 12. More specifically, the inverter 130 shapes the voltage generated by the electrons multiplied by the light-receiving element 12. The inverter 130 then outputs a light-receiving signal (APD OUT) in which a pulse waveform illustrated in FIG. 4 is generated, for example, with an arrival time of one font as a starting point, to the arithmetic processing section. For example, the arithmetic processing section performs arithmetic processing, in each light-receiving signal, for determining a distance to a subject on the basis of a timing at which the pulse indicating the arrival time of one font is generated, and determines the distance for each of the unit pixels P. On the basis of the distances, a distance image is then generated in which the distances to the subject detected by the plurality of unit pixels P are arranged in a planar manner.

The photodetector 1 is, for example, a so-called back side illumination photodetector in which a logic substrate 20 is stacked on a side of a front surface of a sensor substrate 10 (e.g., a side of a front surface (a first surface 11S1) of a semiconductor substrate 11 constituting the sensor substrate 10), and receives light from a side of a back surface of the sensor substrate 10 (e.g., a back surface (a second surface 11S2) of the semiconductor substrate 11 constituting the sensor substrate 10).

The photodetector 1 includes the light-receiving element 12 for each of the unit pixels P. The light-receiving element 12 includes a light-receiving section 13 and a multiplication section 14. In the photodetector 1, the sensor substrate 10 and the logic substrate 20 are stacked, as described above. The sensor substrate 10 includes, for example, the semiconductor substrate 11 configured by a silicon substrate, and a multilayer wiring layer 19 provided on the side of the first surface 11S1 of the semiconductor substrate 11. The light-receiving section 13 and the multiplication section 14 are formed to be embedded in the semiconductor substrate 11, for example. The semiconductor substrate 11 further includes a pixel separation section 17 that electrically separates adjacent unit pixels P from each other. The pixel separation section 17 is provided between the plurality of unit pixels P adjacent to each other in the row direction and the column direction to extend from the first surface 11S1 to the second surface 11S2 of the semiconductor substrate 11. The pixel separation section 17 is provided in a lattice pattern in a plan view in the entire pixel array section 100A. The semiconductor substrate 11 further includes a contact layer 15 (anode) electrically coupled to the light-receiving section 13, and a contact layer 16 (cathode) electrically coupled to the multiplication section 14. In the present embodiment, a via Vla that electrically couples the contact layer 15 and a portion of wiring of a wiring layer 191, for example, to each other is formed independently for each of the unit pixels P, in the multilayer wiring layer 19 provided on the first surface 11S1 of the semiconductor substrate 11.

It is to be noted that the symbols “p” and “n” in the diagram represent a p type semiconductor region and an n type semiconductor region, respectively. Further, “+” and “−” at the end of “p” each represent an impurity concentration of the p type semiconductor region. Likewise, “+” and “−” at the end of “n” each represent an impurity concentration of the n type semiconductor region. Here, larger numbers of “+” indicate higher impurity concentration, and larger numbers of “−” indicate lower impurity concentration. The same applies to the following drawings.

The semiconductor substrate 11 has the first surface 11S1 and the second surface 11S2 opposed to each other. The semiconductor substrate 11 includes a p-well (p) common to the plurality of unit pixels P. The semiconductor substrate 11 is provided, for each of the unit pixels P, with an n-type semiconductor region (n) 111 in which an impurity concentration is controlled to an n-type, for example, that constitutes the light-receiving section 13. The semiconductor substrate 11 is further provided with a p-type semiconductor region (p+) 14X and an n-type semiconductor region (n+) 14Y that constitute the multiplication section 14 on the side of the first surface 11S1. This allows for formation of the light-receiving element 12 for each of the unit pixels P. The pixel separation section 17 that electrically separates the adjacent unit pixels P from each other is provided around the unit pixel P. A p-type semiconductor region (p) 112 having a higher impurity concentration than that of the p-well is provided between the light-receiving element 12 and the pixel separation section 17.

The light-receiving element 12 has a multiplication region (avalanche multiplication region 12X) that performs avalanche multiplication of carriers by a high electric field region. As described above, the light-receiving element 12 is the SPAD element that enables the formation of the avalanche multiplication region 12X by a large negative voltage applied to the cathode (contact layer 16) and that enables the avalanche multiplication of electrons generated by the incidence of one photon.

The light-receiving element 12 is configured by the light-receiving section 13 and the multiplication section 14.

The light-receiving section 13 corresponds to a specific example of a “light-receiving section” of the present disclosure. The light-receiving section 13 has a photoelectric conversion function of absorbing light incident from the side of the second surface 11S2 of the semiconductor substrate 11 and generating carriers corresponding to the received light amount. As described above, the light-receiving section 13 includes the n-type semiconductor region (n) 111 of which an impurity concentration is controlled to an n-type, and carriers (electrons) generated by the light-receiving section 13 are transferred to the multiplication section 14 by a potential gradient.

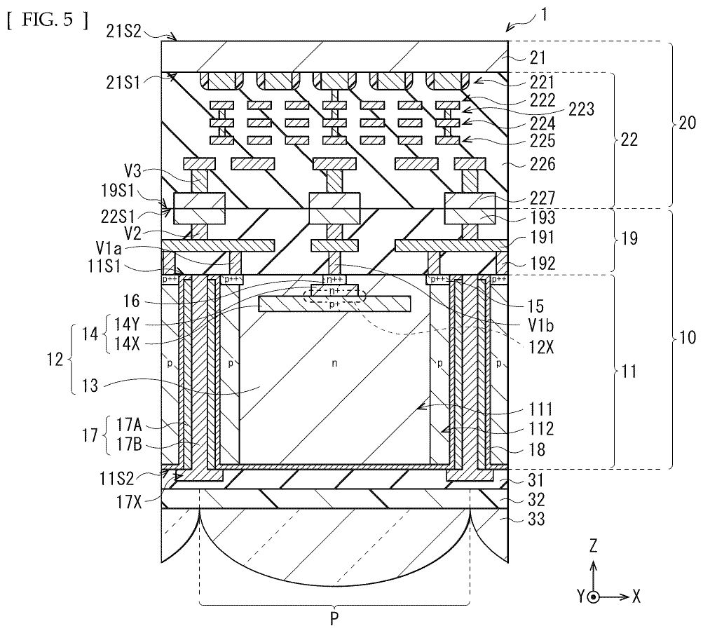

The multiplication section 14 corresponds to a specific example of a “multiplication section” of the present disclosure. The multiplication section 14 performs avalanche multiplication of carriers (here, electrons) generated by the light-receiving section 13. The multiplication section 14 is configured by, for example, the p-type semiconductor region (p⁺) 14X having an impurity concentration higher than that of the p-well (p), and the n-type semiconductor region (n⁺) 14Y having an impurity concentration higher than that of the n-type semiconductor region (n) 111. The p-type semiconductor region (p⁺) 14X and the n-type semiconductor region (n⁺) 14Y are provided on the side of the first surface 11S1. The n-type semiconductor region (n⁺) 14Y and the p-type semiconductor region (p⁺) 14X are formed to be stacked in this order from the side of the first surface 11S1. An area of the p-type semiconductor region (p⁺) 14X in an X-Y plane direction is larger than an area of the n-type semiconductor region (n⁺) 14Y in the X-Y plane direction, and is provided across the entire surface of the unit pixel P partitioned by the pixel separation section 17, for example. However, this is not limitative, and, for example, the p-type semiconductor region (p⁺) 14X may be formed on an inner side of the p-type semiconductor region (p) 112, as illustrated in FIG. 5, for example.

In the light-receiving element 12, the avalanche multiplication region 12X is formed at a junction part between the p-type semiconductor region (p⁺) 14X and the n-type semiconductor region (n⁺) 14Y. The avalanche multiplication region 12X is a high electric field region (depletion layer) formed at an interface between the p-type semiconductor region (p⁺) 14X and the n-type semiconductor region (n⁺) 14Y by a large negative voltage applied to the cathode. In the avalanche multiplication region 12X, electrons (e⁻) generated by one photon incident on the light-receiving element 12 are multiplied.

The first surface 11S1 of the semiconductor substrate 11 is further provided with the contact layer 15 and the contact layer 16. The contact layer 15 includes a p-type semiconductor region (p⁺⁺) electrically coupled to the n-type semiconductor region (n) 111 constituting the light-receiving section 13. The contact layer 16 includes an n-type semiconductor region (n⁺⁺) electrically coupled to the n-type semiconductor region (n⁺) 14Y constituting the multiplication section 14. As illustrated in (A) of FIG. 2, for example, the contact layer 15 is provided along the pixel separation section 17 to surround the light-receiving section 13, and is coupled to the bias voltage application section 110 as the anode of the light-receiving element 12. The contact layer 16 is coupled as the cathode to the source terminal of the quenching resistance element 120.

The pixel separation section 17 electrically separates adjacent unit pixels P from each other, and is provided in a lattice pattern, for example, in a plan view to partition the plurality of unit pixels P from each other in the pixel array section 100A. The pixel separation section 17 extends from the first surface 11S1 to the second surface 11S2 of the semiconductor substrate 11, and penetrates the semiconductor substrate 11, for example. The pixel separation section 17 is configured by, for example, an insulating film 17A and a light-blocking film 17B embedded in the insulating film 17A. The pixel separation section 17 may be provided from the side of the first surface 11S1 of the semiconductor substrate 11 or may be formed from the side of the second surface 11S2 of the semiconductor substrate 11.

The insulating film 17A is formed using, for example, silicon oxide (SiOₓ) or the like. The light-blocking film 17B is formed using, for example, a metal material having a light-blocking property, such as tungsten (W), aluminum (Al), copper (Cu), cobalt (Co), nickel (Ni), or titanium (Ti), or a silicon compound thereof. In addition thereto, the light-blocking film 17B may be formed using polysilicon (Poly-Si). The light-blocking film 17B may be provided with an increased width section 17X formed to be extended on the second surface 11S2 of the semiconductor substrate 11, for the purpose of suppressing incidence of oblique incident light between adjacent unit pixels P.

A side surface and a bottom surface of the pixel separation section 17 and the second surface 11S2 of the semiconductor substrate 11 may be provided with, for example, a layer having fixed electric charge (a fixed charge film 18). The fixed charge film 18 may be a film having positive fixed electric charge or a film having negative fixed electric charge.

It is preferable to use, as a constituent material of the fixed charge film 18, a semiconductor material or electrically-conductive material having a wider band gap than that of the semiconductor substrate 11 for the formation. This makes it possible to suppress generation of a dark current at the interface of the semiconductor substrate 11. Examples of the constituent material of the fixed charge film 18 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}).

The multilayer wiring layer 19 is provided on the side of the first surface 11S1 of the semiconductor substrate 11. In the multilayer wiring layer 19, the wiring layer 191 including one or a plurality of pieces of wiring is formed in an interlayer insulating layer 192. The wiring layer 191 is provided, for example, to supply a voltage to be applied to the semiconductor substrate 11 or the light-receiving element 12, or to extract carriers generated in the light-receiving element 12. A portion of the wiring of the wiring layer 191 is electrically coupled to the contact layer 15 through a via V1b. In addition, a portion of the wiring of the wiring layer 191 is electrically coupled to the contact layer 16 through the via V1b. A plurality of pad electrodes 193 is embedded in a front surface (a front surface 19S1 of the multilayer wiring layer 19), of the interlayer insulating layer 192, on a side opposite to the side of the semiconductor substrate 11. The plurality of pad electrodes 193 is electrically coupled to a portion of wiring of the wiring layer 191 through a via V2. It is to be noted that FIG. 1 illustrates an example in which one wiring layer 191 is formed in the multilayer wiring layer 19; however, the total number of wiring layers in the multilayer wiring layer 19 is not limited, and two or more wiring layers may be formed.

The Via Vla that electrically couples the contact layer 15 and a portion of wiring of the wiring layer 191 to each other corresponds to a specific example of “connection wiring” of the present disclosure. In the present embodiment, for example, as illustrated in (B) of FIG. 2, the via Vla is formed continuously along an outer shape of the unit pixel P independently for each of the unit pixels P. Specifically, as illustrated in (A) of FIG. 2, for example, the via Vla is formed, as a rectangular frame body, independently for each of the unit pixels P, to be coupled to the contact layer 15 provided to surround the light-receiving section 13 along the pixel separation section 17, on an inner side of the unit pixel P than the pixel separation section 17 provided in a lattice pattern. This reduces light leakage due to, for example, reflection of internal luminescence, which has been generated during avalanche multiplication of adjacent unit pixels P, by the wiring layer 191, for example, formed in the multilayer wiring layer 19.

The interlayer insulating layer 192 includes, for example, a monolayer film including one of silicon oxide (SiOₓ), TEOS, silicon nitride (SiNₓ), silicon oxynitride (SiOₓN_{y}), or the like, or a stacked film including two or more thereof.

The wiring layer 191 is formed using, for example, aluminum (Al), copper (Cu), tungsten (W), or the like.

The Vias V1a, V1b, and V2 are formed using, for example, a metal material having a light-blocking property, such as tungsten (W), aluminum (Al), copper (Cu), cobalt (Co), nickel (Ni), or titanium (Ti), or a silicon compound thereof. In addition thereto, the vias V1a, V1b, and 2 may be formed using polysilicon (Poly-Si).

The pad electrode 193 is exposed on a bonded surface with the logic substrate 20 (the front surface 19S1 of the multilayer wiring layer 19), and is used, for example, to be coupled to the logic substrate 20. The pad electrode 193 is formed using copper (Cu), for example.

The logic substrate 20 includes, for example, a semiconductor substrate 21 configured by a silicon substrate, and a multilayer wiring layer 22. The logic substrate 20 includes a logic circuit which includes, for example, the above-described bias voltage application section 110 including, for example, a cathode voltage generation circuit 51, an anode voltage generation circuit 52, and a modulation voltage generation circuits 53A and 53B, a readout circuit that outputs a pixel signal based on electric charge outputted from the unit pixel P of the pixel array section 100A, a vertical drive circuit, a column signal processing circuit, a horizontal drive circuit, an output circuit, and the like.

In the multilayer wiring layer 22, for example, a gate wiring 221 of a transistor constituting the readout circuit and wiring layers 222, 223, 224, and 225 each including one or a plurality of pieces of wiring are stacked in order from a side of the semiconductor substrate 21 with an interlayer insulating layer 226 interposed therebetween. A plurality of pad electrodes 227 is embedded in a front surface, of the interlayer insulating layer 226 (a front surface 22S1 of the multilayer wiring layer 22), on a side opposite to the side of the semiconductor substrate 21. The plurality of pad electrodes 227 is electrically coupled to a portion of the wiring of the wiring layer 225 through a via V3.

In the same manner as the interlayer insulating layer 192, the interlayer insulating layer 117 is configured by, for example, a monolayer film including one of silicon oxide (SiOₓ), TEOS, silicon nitride (SiNₓ), silicon oxynitride (SiOₓN_{y}), or the like, or a stacked film including two or more thereof.

In the same manner as the wiring layer 191, the gate wiring 221 and the wiring layers 222, 223, 224, and 225 are formed using, for example, aluminum (Al), copper (Cu), tungsten (W), or the like.

The pad electrode 227 is exposed on a bonded surface with the sensor substrate 10 (the front surface 22S1 of the multilayer wiring layer 22), and is used, for example, to be coupled to the sensor substrate 10. In the same manner as the pad electrode 193, the pad electrode 227 is formed using, for example, copper (Cu).

In the photodetector 1, for example, Cu—Cu bonding is made between the pad electrode 193 and the pad electrode 227. This allows the cathode of the light-receiving element 12 to be electrically coupled to the quenching resistance element 120 provided on a side of the logic substrate 20, and the anode of the light-receiving element 12 is electrically coupled to the bias voltage application section 110.

On a side of a light-receiving surface (second surface 11S2) of the semiconductor substrate 11, for example, a microlens 33 is provided for each of the unit pixels P with a protective layer 31 and a color filter 32 being interposed therebetween.

The microlens 33 condenses light incident from above to the light-receiving element 12, and is formed using, for example, silicon oxide (SiOₓ), or the like.

### (1-2. Workings and Effects)

In the photodetector 1 of the present embodiment, the connection wiring (via V1a) is provided independently for each of the unit pixels P. The connection wiring (via V1a) electrically couples the contact layer 15 and a portion of wiring of the wiring layer 191 in the multilayer wiring layer 19 provided on the side of the first surface 11S1 of the semiconductor substrate 11 to each other. The contact layer 15 is provided along the pixel separation section 17 on the first surface 11S1 of the semiconductor substrate 11, and is electrically coupled to the light-receiving section 13. This reduces leaked light from adjacent unit pixels P. This is described below.

In the technology of the SPAD, a high bias voltage is applied to multiply carriers generated by photoelectric conversion of incident light, thereby enabling extraction thereof as a large signal.

In such a photodetector in which the SPAD elements are arranged in array, it is known that crosstalk occurs due to leakage of internal luminescence, which is generated during avalanche multiplication, into adjacently arranged pixels; suppression of the crosstalk is required.

In contrast, in the present embodiment, the via V1a is provided, as a rectangular frame body, for example, independently for each of the unit pixels P. The via V1a electrically couples the contact layer 15 and a portion of wiring of the wiring layer 191 in the multilayer wiring layer 19 provided on the side of the first surface 11S1 of the semiconductor substrate 11 to each other. The contact layer 15 is provided along the pixel separation section 17 on the first surface 11S1 of the semiconductor substrate 11, and is electrically coupled to the light-receiving section 13. This reduces leaked light from adjacent unit pixels P, for example.

As described above, it is possible, in the photodetector 1 of the present embodiment, to, for example, reduce crosstalk between adjacently arranged unit pixels P without interfering with the pixel separation section 17, of a so-called full trench type, that penetrates the semiconductor substrate 11 from the first surface 11S1 to the second surface 11S2.

Next, description is given of second to fourth embodiments and Modification Examples 1 to 7 of the present disclosure as well as an application example and practical application examples. Hereinafter, components similar to those of the foregoing first embodiment are denoted by the same reference numerals, and descriptions thereof are omitted as appropriate.

### 2. MODIFICATION EXAMPLES

### 2-1. Modification Example 1

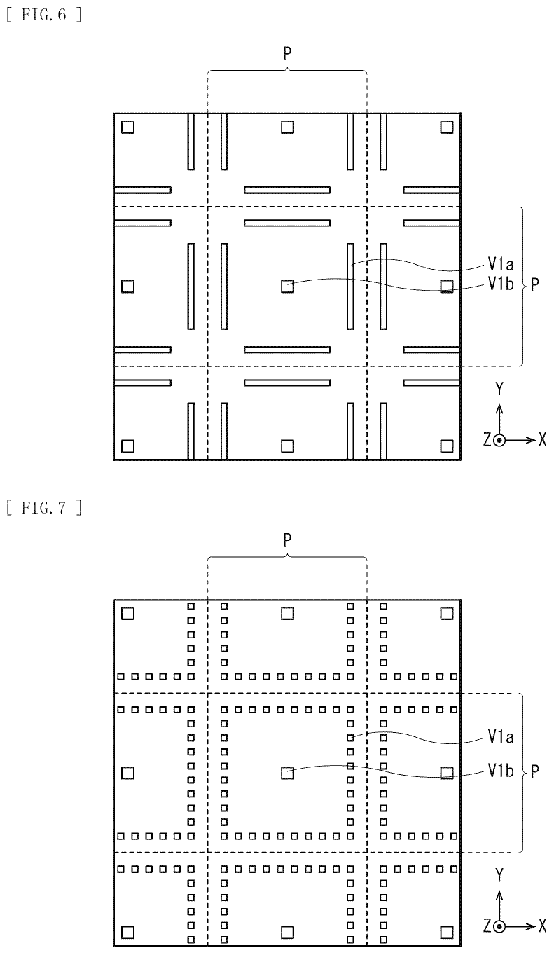

FIG. 6 schematically illustrates a planar configuration, corresponding to the line II-II, of the photodetector 1 illustrated in FIG. 1, according to a modification example (Modification Example 1) of the foregoing first embodiment. The foregoing first embodiment exemplifies the connection wiring (via V1a), which electrically couples the contact layer 15 and a portion of wiring of the wiring layer 191 to each other, being provided as a rectangular frame body independently for each of the unit pixels P; however, this is not limitative.

For example, as illustrated in FIG. 6, the via V1a may be provided along sides of each of the unit pixels P having a rectangular shape and being adjacent to each other in the row direction and the column direction, except intersections of the unit pixels P adjacent to each other in an oblique direction.

This makes it possible to form the via V1a more easily than the via V1a having the continuous frame body shape, although the effect of reducing the crosstalk is lower than that of the foregoing first embodiment.

### 2-2. Modification Example 2

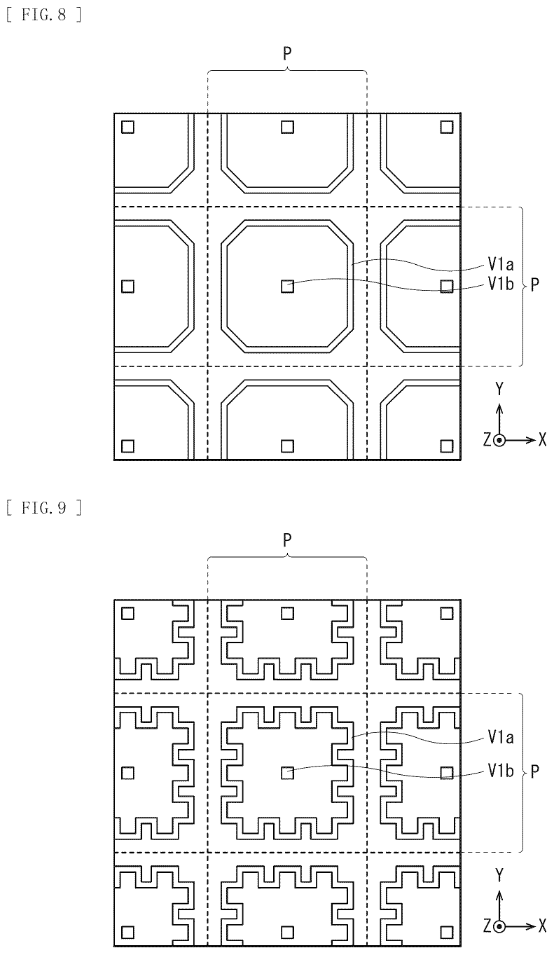

FIG. 7 schematically illustrates a planar configuration, corresponding to the line II-II, of the photodetector 1 illustrated in FIG. 1, according to a modification example (Modification Example 2) of the foregoing first embodiment. The foregoing first embodiment exemplifies the connection wiring (via V1a), which electrically couples the contact layer 15 and a portion of wiring of the wiring layer 191 to each other, being provided as a rectangular frame body independently for each of the unit pixels P; however, this is not limitative.

For example, as illustrated in FIG. 7, the via V1a may be formed in a dotted manner along the outer shape of the unit pixel P.

This makes it possible to suppress a decrease in external quantum efficiency due to light absorption at the via V1a, although the reduction effect in the crosstalk is lowered as compared with the foregoing first embodiment.

### 2-3. Modification Example 3

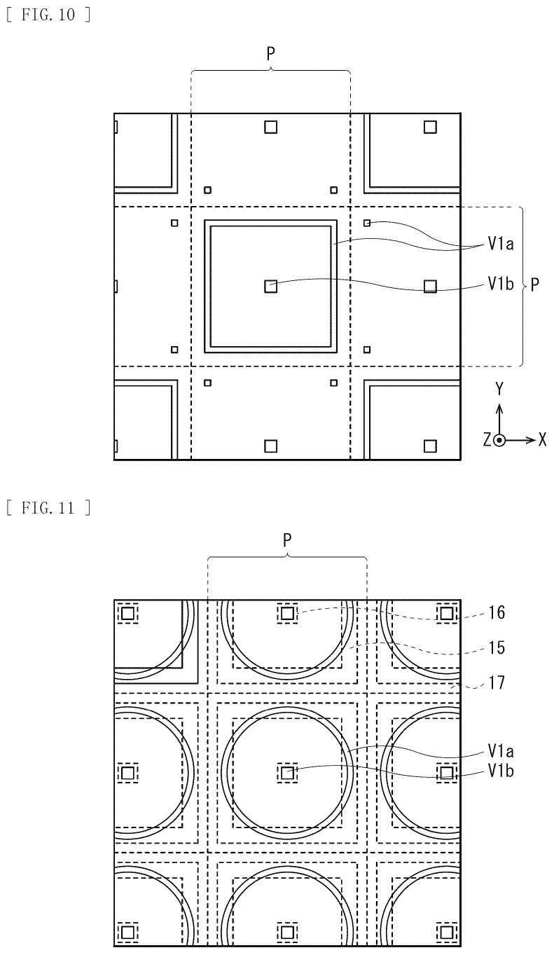

FIG. 8 schematically illustrates a planar configuration, corresponding to the line II-II, of the photodetector 1 illustrated in FIG. 1, according to a modification example (Modification Example 3) of the foregoing first embodiment. The foregoing first embodiment exemplifies the connection wiring (via V1a), which electrically couples the contact layer 15 and a portion of wiring of the wiring layer 191 to each other, being provided as a rectangular frame body independently for each of the unit pixels P; however, this is not limitative.

In the via V1a, for example, as illustrated in FIG. 8, a corner of the rectangular frame body may have an obtuse angle.

This achieves an effect of making it possible to reduce concentration of stress at the corner, in addition to the effects of the foregoing first embodiment.

### 2-4. Modification Example 4

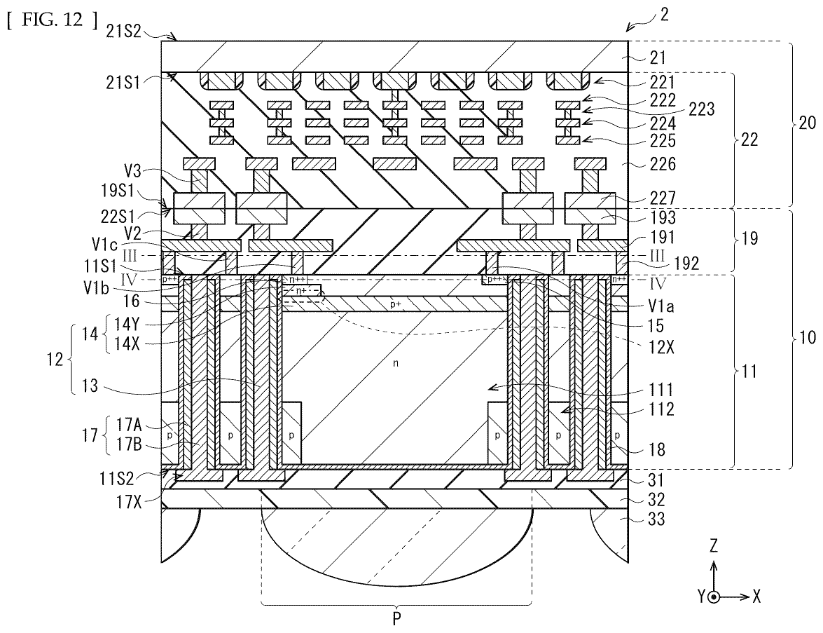

FIG. 9 schematically illustrates a planar configuration, corresponding to the line II-II, of the photodetector 1 illustrated in FIG. 1, according to a modification example (Modification Example 4) of the foregoing first embodiment. The foregoing first embodiment exemplifies the connection wiring (via V1a), which electrically couples the contact layer 15 and a portion of wiring of the wiring layer 191 to each other, being provided as a rectangular frame body independently for each of the unit pixels P; however, this is not limitative.

For example, as illustrated in FIG. 9, the via V1a may be formed in a meandering manner along the outer shape of the unit pixel P.

This increases reflected light by an interface of the via V1a, as compared with the via V1a of the foregoing first embodiment. It is therefore possible to improve external quantum efficiency, in addition to the effects of the foregoing first embodiment. (2-5. Modification Example 5)

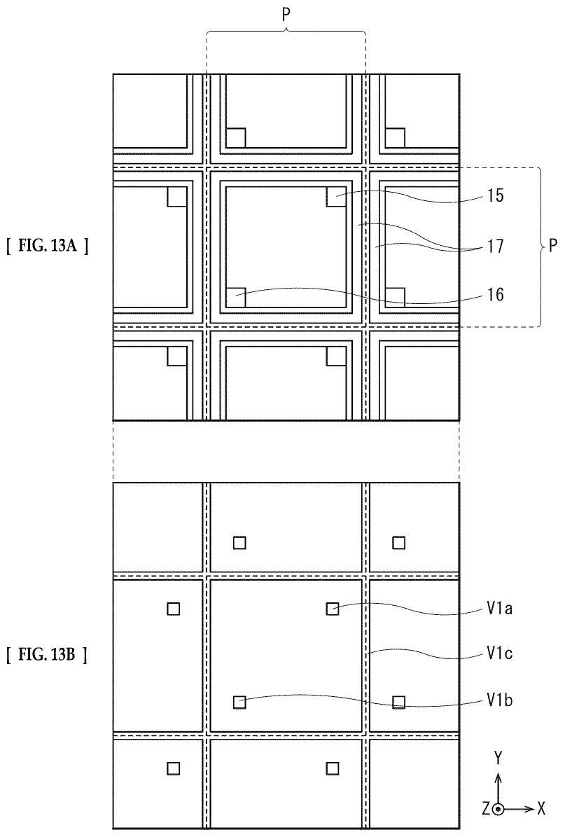

FIG. 10 schematically illustrates a planar configuration, corresponding to the line II-II, of the photodetector 1 illustrated in FIG. 1, according to a modification example (Modification Example 5) of the foregoing first embodiment. The foregoing first embodiment exemplifies the frame body-shaped connection wiring (via V1a), which electrically couples the contact layer 15 and a portion of wiring of the wiring layer 191 to each other, being provided in all of the plurality of unit pixels P that constitute the pixel array section 100A; however, this is not limitative.

In the pixel array section 100A configured by the plurality of unit pixels P arranged in array in the row direction and the column direction, for example, the frame body-shaped via V1a formed independently for each of the unit pixels P may be provided at every other pixel in an X-axis direction and a Y-axis direction. In the unit pixel P where no frame body-shaped via V1a is formed, for example, as illustrated in FIG. 10, the via V1a is formed at each of four corners of the unit pixel P having a rectangular shape.

As described above, even in a case where the frame body-shaped vias V1a are provided in a staggered manner in the pixel array section 100A, it is possible to obtain effects similar to those of the foregoing first embodiment.

### 2-6. Modification Example 6

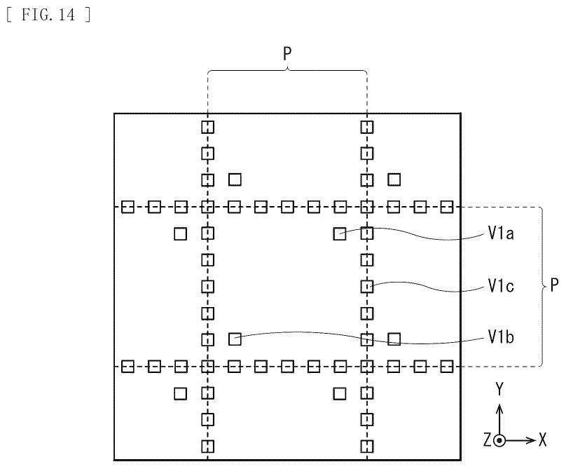

FIG. 11 schematically illustrates a planar configuration, corresponding to the line II-II, of the photodetector 1 illustrated in FIG. 1, according to a modification example (Modification Example 6) of the foregoing first embodiment. The foregoing first embodiment exemplifies the connection wiring (via V1a), which electrically couples the contact layer 15 and a portion of wiring of the wiring layer 191 to each other, being provided as a rectangular frame body independently for each of the unit pixels P; however, this is not limitative.

For example, as illustrated in FIG. 11, the via V1a may have a shape of a circular frame body (ring shape). As illustrated in FIG. 11, the ring-shaped via V1a is coupled to each side of the contact layer 15 provided in a rectangular shape.

As described above, even in a case where the connection wiring (via V1a), which electrically couples the contact layer 15 and a portion of wiring of the wiring layer 191 to each other, is formed in a ring shape, it is possible to obtain to obtain effects similar to those of the foregoing first embodiment.

### 3.Second Embodiment

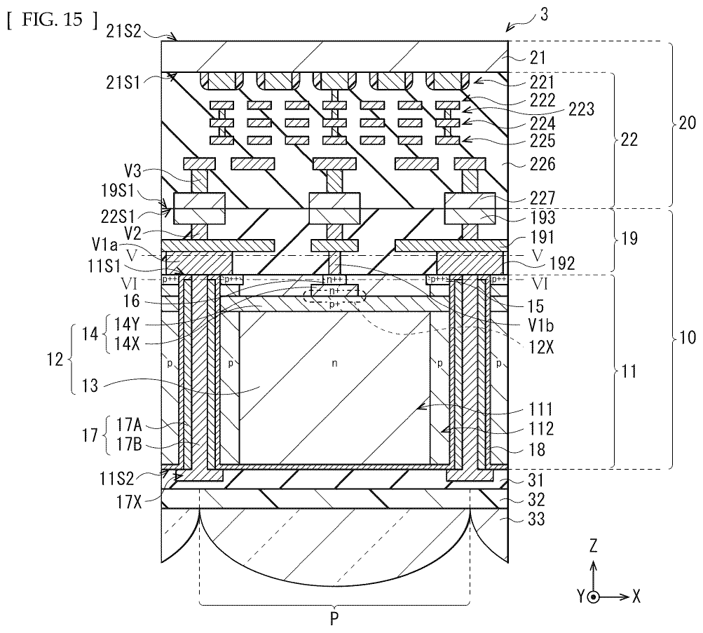

FIG. 12 schematically illustrates an example of a cross-sectional configuration of a photodetector (a photodetector 2) according to a second embodiment of the present disclosure. FIG. 13 schematically illustrates planar configurations of the photodetector 1 illustrated in FIG. 12 corresponding to a line III-III (A) and a line IV-IV (B). In the same manner as the photodetector 1 of the foregoing first embodiment, the photodetector 2 is applied to, for example, a distance image sensor (the distance image apparatus 1000 described later) that performs distance measurement by the ToF method, an image sensor, or the like.

In the same manner as the foregoing first embodiment, the photodetector 2 includes the light-receiving element 12 for each of the unit pixels P. The light-receiving element 12 includes the light-receiving section 13 and the multiplication section 14. In the photodetector 2, the sensor substrate 10 and the logic substrate 20 are stacked. The sensor substrate 10 includes, for example, the semiconductor substrate 11 configured by a silicon substrate, and the multilayer wiring layer 19 provided on the side of the first surface 11S1 of the semiconductor substrate 11. The light-receiving section 13 and the multiplication section 14 are formed to be embedded in the semiconductor substrate 11, for example. The semiconductor substrate 11 further includes the pixel separation section 17 that electrically separates adjacent unit pixels P from each other. The pixel separation section 17 extends from the first surface 11S1 to the second surface 11S2 of the semiconductor substrate 11. The semiconductor substrate 11 further includes the contact layer 15 (anode) electrically coupled to the light-receiving section 13, and the contact layer 16 (cathode) electrically coupled to the multiplication section 14. The contact layer 15 and the contact layer 16 are each provided on a diagonal line in the unit pixel P having a rectangular shape, for example.

In the present embodiment, the pixel separation section 17 is provided independently for each of the plurality of unit pixels P arranged in array in the row direction and the column direction in the pixel array section 100A. Accordingly, as illustrated in FIG. 12, the photodetector 2 has a cross-sectional structure in which two pixel separation sections 17 are arranged side by side between the unit pixels P adjacent to each other.

In addition, in the present embodiment, a via V1c is further provided between the unit pixels P adjacent to each other in the row direction and the column direction, in addition to the via V1a that electrically couples the contact layer 15 and a portion of wiring of the wiring layer 191, for example, to each other, and the via V1b that electrically couples the contact layer 16 and a portion of wiring of the wiring layer 191, for example, to each other, in the multilayer wiring layer 19 provided on the first surface 11S1 of the semiconductor substrate 11. The via V1c is provided in a lattice pattern in a plan view across the entire pixel array section 100A. A top surface of the via V1c is in contact with the first surface 11S1 of the semiconductor substrate 11 between two pixel separation sections 17 provided side by side between the adjacent unit pixels P, and an undersurface of the via V1c is in contact with a portion of wiring of the wiring layer 191 coupled to the via V1a, for example. The via V1c corresponds to a specific example of “connection wiring” of the present disclosure.

As described above, in the present embodiment, the connection wiring (via V1c) in contact with the first surface 11S1 of the semiconductor substrate 11 and with a portion of wiring of the wiring layer 191 is provided between the unit pixels P adjacent to each other in the row direction and the column direction. The connection wiring (via V1c) is formed in a lattice pattern in a plan view across the entire pixel array section. This reduces leaked light from adjacent unit pixels P, for example. In addition, the pixel separation section 17 is provided independently for each of the unit pixels P inside the via V1c provided in a lattice pattern in a plan view. Further, the contact layers 15 and 16 are provided on a diagonal line in the unit pixel P having a rectangular shape, for example. This enables the anode (contact layer 15) and the cathode (contact layer 16) to be distanced from each other.

As described above, in the photodetector 2 of the present embodiment, it is possible to reduce crosstalk between adjacently arranged unit pixel P, in the same manner as the foregoing first embodiment. Additionally, it is possible to suppress edge breakdown.

### 4. Modification Example 7

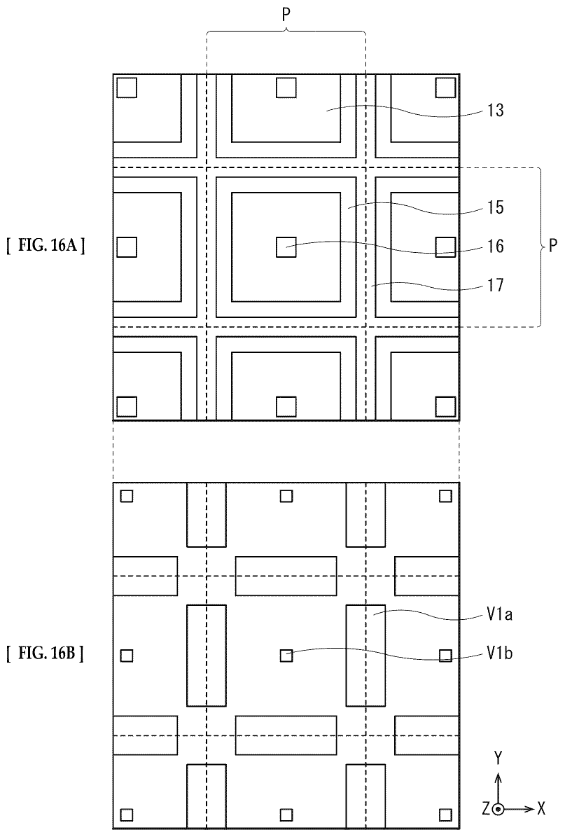

FIG. 14 schematically illustrates a planar configuration, corresponding to a line IV-IV, of the photodetector 2 illustrated in FIG. 12, according to a modification example (Modification Example 7) of the second embodiment. The second embodiment exemplifies the connection wiring (via V1c) being provided in a lattice pattern; however, this is not limitative.

For example, as illustrated in FIG. 14, the via V1c may be formed in a dotted manner.

This makes it possible to suppress a decrease in external quantum efficiency due to light absorption at the via V1c, although the reduction effect in the crosstalk is lowered, as compared with the foregoing second embodiment.

### 5.Third Embodiment

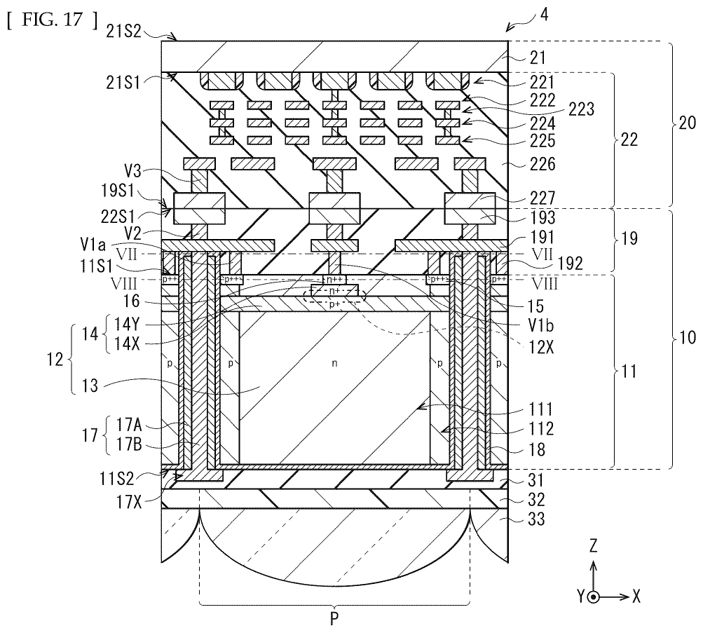

FIG. 15 schematically illustrates an example of a cross-sectional configuration of a photodetector (a photodetector 3) according to a third embodiment of the present disclosure. FIG. 16 schematically illustrates planar configurations of the photodetector 1 illustrated in FIG. 15 corresponding to a line V-V (A) and a line VI-VI (B). In the same manner as the photodetector 1 of the foregoing first embodiment, the photodetector 3 is applied to, for example, a distance image sensor (the distance image apparatus 1000 described later) that performs distance measurement by the ToF method, an image sensor, or the like.

In the same manner as the foregoing first embodiment, the photodetector 3 includes the light-receiving element 12 for each of the unit pixels P. The light-receiving element 12 includes the light-receiving section 13 and the multiplication section 14. In the photodetector 3, the sensor substrate 10 and the logic substrate 20 are stacked. The sensor substrate 10 includes, for example, the semiconductor substrate 11 configured by a silicon substrate, and the multilayer wiring layer 19 provided on the side of the first surface 11S1 of the semiconductor substrate 11. The light-receiving section 13 and the multiplication section 14 are formed to be embedded in the semiconductor substrate 11, for example. The semiconductor substrate 11 further includes the pixel separation section 17 that electrically separates adjacent unit pixels P from each other. The pixel separation section 17 is provided between the plurality of unit pixels P adjacent to each other in the row direction and the column direction to extend from the first surface 11S1 to the second surface 11S2 of the semiconductor substrate 11. The pixel separation section 17 is provided in a lattice pattern in a plan view in the entire pixel array section 100A. The semiconductor substrate 11 further includes the contact layer 15 (anode) electrically coupled to the light-receiving section 13, and the contact layer 16 (cathode) electrically coupled to the multiplication section 14.

In the present embodiment, the via V1a is formed to straddle the pixel separation section 17 to allow adjacent contact layers 15 to be electrically coupled to a portion of wiring of the wiring layer 191 collectively, with the pixel separation section 17 therebetween, in the unit pixels P adjacent to each other in the row direction and the column direction.

That is, unlike the via V1a of the foregoing first embodiment provided on an inner side of the unit pixel P than the pixel separation section 17 in a plan view, the via V1a of the present embodiment is provided to overlap the pixel separation section 17 in a plan view.

Particularly, as illustrated in (B) of FIG. 16, for example, the via V1a is thicker than a line width of the pixel separation section 17, and is provided along sides of each of the unit pixels P having a rectangular shape and being adjacent to each other in the row direction and the column direction, except intersections of the unit pixels P adjacent to each other in the oblique direction.

As described above, in the present embodiment, the connection wiring (via V1a), which electrically couples the contact layer 15 electrically coupled to the light-receiving section 13 and a portion of wiring of the wiring layer 191 in the multilayer wiring layer 19 provided on the side of the first surface 11S1 of the semiconductor substrate 11 to each other, is provided along sides of each of the unit pixels P having a rectangular shape and being adjacent to each other in the row direction and the column direction, except the intersections of the unit pixels P adjacent to each other in the oblique direction. This reduces leaked light from adjacent unit pixels P, for example.

As described above, in the same manner as the foregoing first embodiment, it is possible, in the photodetector 3 of the present embodiment, to, for example, reduce crosstalk between adjacently arranged unit pixels P without interfering with the pixel separation section 17, of a so-called full trench type, that penetrates the semiconductor substrate 11 from the first surface 11S1 to the second surface 11S2.

In addition, in the photodetector 3 of the present embodiment, the via V1a that is thicker than the linewidth of the pixel separation section 17 is formed to straddle the pixel separation section 17, thus enabling the contact layers 15 adjacent to each other with the pixel separation section 17 interposed therebetween to be electrically coupled to a portion of wiring of the wiring layer 191 collectively, in the unit pixels P adjacent to each other in the row direction and the column direction. This makes it possible to reduce a thickness of the contact layer 15, as compared with the case where the via V1a is formed on an inner side of the unit pixel P than the pixel separation section 17 for each of the unit pixels P as in the photodetector 1 of the foregoing first embodiment. This enables the contact layer 15 including the p-type semiconductor region (p⁺⁺) and the contact layer 16 including the n-type semiconductor region (n⁺⁺) to be physically separated from each other, thus making it possible to suppress avalanche multiplication at a pixel edge part.

Further, in the photodetector 3 of the present embodiment, the top surface of via 1a may protrude into the semiconductor substrate 11. This enables the contact layer 15 and the contact layer 16 to be physically separated from each other in a thickness direction (a Z-axis direction) of the semiconductor substrate 11, thus making it possible to further suppress the avalanche multiplication at the pixel edge part.

### 6. Fourth Embodiment

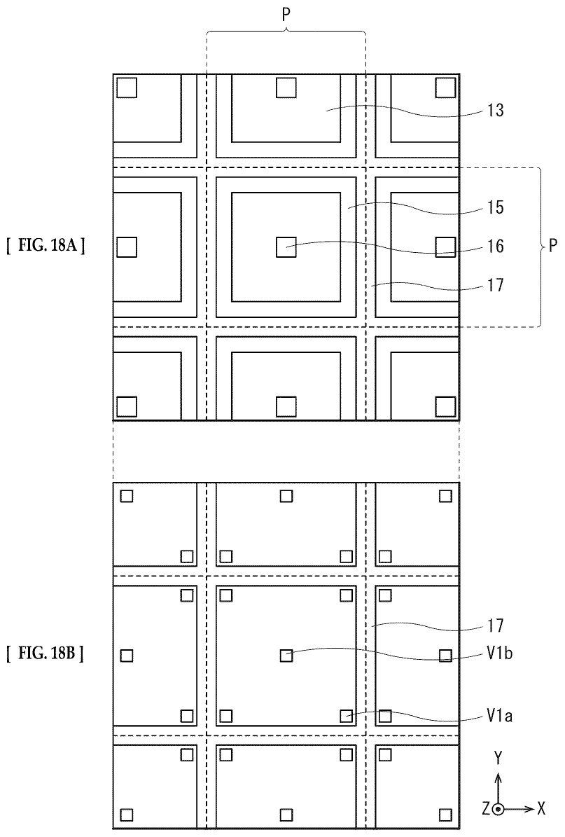

FIG. 17 schematically illustrates an example of a cross-sectional configuration of a photodetector (a photodetector 4) according to a fourth embodiment of the present disclosure. FIG. 18 schematically illustrates planar configurations of the photodetector 1 illustrated in FIG. 17 corresponding to a line VII-VII (A) and a line VIII-VIII (B). In the same manner as the photodetector 1 of the foregoing first embodiment, the photodetector 4 is applied to, for example, a distance image sensor (the distance image apparatus 1000 described later) that performs distance measurement by the ToF method, an image sensor, or the like.

In the same manner as the foregoing first embodiment, the photodetector 4 includes the light-receiving element 12 for each of the unit pixels P. The light-receiving element 12 includes the light-receiving section 13 and the multiplication section 14. In the photodetector 4, the sensor substrate 10 and the logic substrate 20 are stacked. The sensor substrate 10 includes, for example, the semiconductor substrate 11 configured by a silicon substrate, and the multilayer wiring layer 19 provided on the side of the first surface 11S1 of the semiconductor substrate 11. The light-receiving section 13 and the multiplication section 14 are formed to be embedded in the semiconductor substrate 11, for example. The semiconductor substrate 11 further includes the pixel separation section 17 that electrically separates adjacent unit pixels P from each other. In the same manner as the foregoing first embodiment, the pixel separation section 17 is provided between the plurality of unit pixels P adjacent to each other in the row direction and the column direction. The pixel separation section 17 is provided in a lattice pattern in a plan view in the entire pixel array section 100A. The semiconductor substrate 11 further includes the contact layer 15 (anode) electrically coupled to the light-receiving section 13, and the contact layer 16 (cathode) electrically coupled to the multiplication section 14.

In the present embodiment, the pixel separation section 17 penetrates the semiconductor substrate 11 from the first surface 11S1 to the second surface 11S2, and reaches, for example, the wiring layer 191 provided in the multilayer wiring layer 19. In the multilayer wiring layer 19 provided on the first surface 11S1 of the semiconductor substrate 11, the via V1a, which couples the contact layer 15 and a portion of wiring of the wiring layer 191, for example, to each other, may be provided as a rectangular frame body independently for each of the unit pixels P in the same manner as the via V1a of the foregoing first embodiment, or may be formed at each of the four corners of the unit pixel P having a rectangular shape, as illustrated in (B) of FIG. 18.

As described above, in the present embodiment, the pixel separation section 17 penetrates the semiconductor substrate 11 from the first surface 11S1 to the second surface 11S2, and further reaches the wiring layer 191 provided in the multilayer wiring layer 19. This reduces leaked light from adjacent unit pixels P, for example.

As described above, it is possible, in the photodetector 4 of the present embodiment, to reduce crosstalk between adjacently arranged unit pixels P.

### 7. Application Example

FIG. 19 illustrates an example of a schematic configuration of a distance image apparatus 1000 as an electronic apparatus including the photodetector (e.g., the photodetector 1) according to the foregoing first to fourth embodiments and Modification Examples 1 to 7. The distance image apparatus 1000 corresponds to a specific example of a “distance measurement apparatus” of the present disclosure.

The distance image apparatus 1000 includes, for example, a light source device 1100, an optical system 1200, the photodetector 1, an image processing circuit 1300, a monitor 1400, and a memory 1500.

The distance image apparatus 1000 receives light (modulated light or pulse light) projected from the light source device 1100 toward an irradiation target 2000 and reflected by a surface of the irradiation target 2000, thereby acquiring a distance image corresponding to a distance to the irradiation target 2000.

The optical system 1200 includes one or a plurality of lenses, and guides image light (incident light) from the irradiation target 2000 to the photodetector 1 to form an image on a light-receiving surface (a sensor unit) of the photodetector 1.

The image processing circuit 1300 performs image processing for constructing the distance image on the basis of a distance signal supplied from the photodetector 1, and the distance image (image data) obtained by the image processing is supplied to the monitor 1400 and displayed, or is supplied to the memory 1500 and stored (recorded).

In the distance image apparatus 1000 configured as described above, application of the above-described photodetector (e.g., the photodetector 1) makes it possible to calculate the distance to the irradiation target 2000 only on the basis of the light-receiving signal from the highly stable unit pixel P, and to generate a highly accurate distance image. That is, the distance image apparatus 1000 is able to acquire a more accurate distance image.

### 8. Practical Application Example

### (Example of Practical Application to Mobile Body)

The technology according to the present disclosure is applicable to a variety of products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

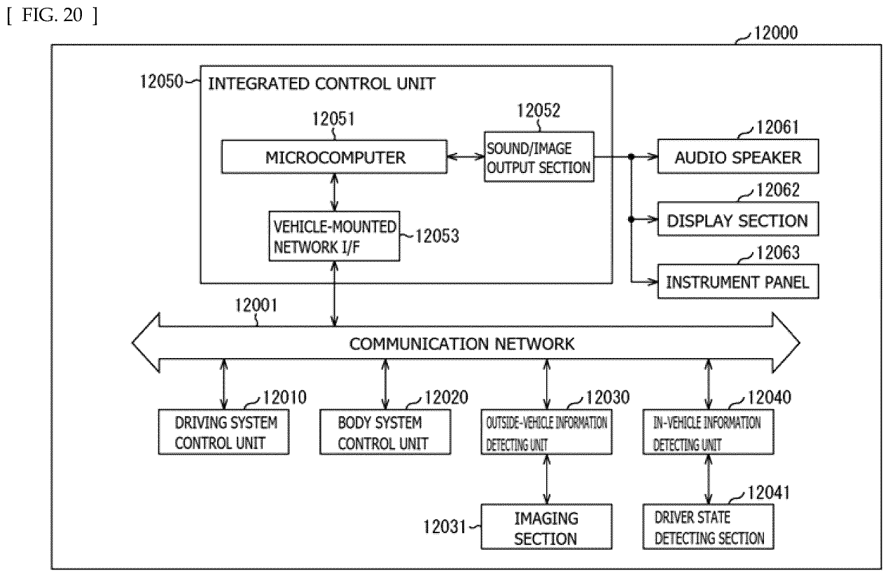

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

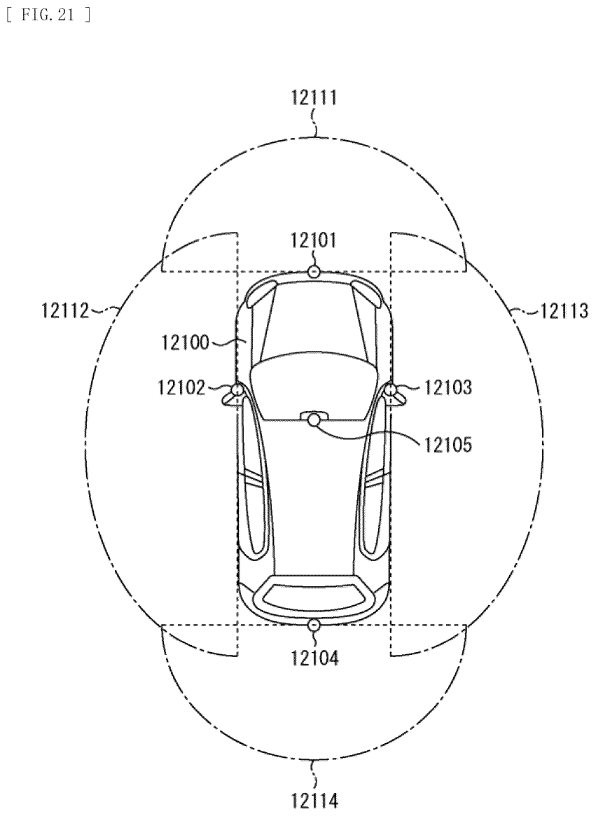

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (e.g., equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Although the description has been given with reference to the first to fourth embodiments, Modification Examples 1 to 7, the application example, and the practical application example, the contents of the present disclosure are not limited to the above-described embodiments and the like. The present disclosure may be modified in a variety of ways. For example, the photodetector of the present disclosure does not have to include all of the components described in the above embodiments and the like, and may include other layers. For example, in a case where the photodetector 1 is to detect light other than visible light (e.g., near-infrared light (IR)), the color filter 32 may be omitted.

In addition, a polarity of the semiconductor region constituting the photodetector according to the present disclosure may be inverted. Further, in the photodetector according to the present disclosure, holes may serve as the signal charge.

Furthermore, as long as the photodetector according to the present disclosure is in a state in which the avalanche multiplication occurs by applying a reverse-bias between the anode and the cathode, the respective potentials are not limited.

In addition, the above embodiment and the like exemplify the semiconductor substrate 11 including silicon; however, the semiconductor substrate 11 may include, for example, germanium (Ge), or a compound semiconductor (e.g., silicon germanium (SiGe)) of silicon (Si) and germanium (Ge).

Further, the shape of the unit pixel P is not limited to the rectangular shape. For example, the unit pixel P may have an octagonal shape, and the plurality of unit pixels P constituting the pixel array section 100A may be arranged in a honeycomb shape.

Furthermore, the technologies described in the foregoing first to fourth embodiments and Modification Examples 1 to 7 may be combined with each other in a feasible range. For example, the foregoing Modification Example 5 exemplifies the frame body-shaped connection wiring (via V1a) being provided in a staggered manner. However, this is also applicable to the connection wiring (via V1a) having the shapes illustrated in Modification Example 1 to 4 described above, thus allowing similar effects to be achieved.

It should be appreciated that the effects described herein are mere examples. The disclosure may include any effects other than those described herein, or may further include other effects in addition to those described herein.

It is to be noted that the present disclosure may have the following configurations. According to the present technology of the following configurations, connection wiring is provided independently for each of a plurality of pixels. The connection wiring electrically couples a first contact layer provided around each of the plurality of pixels along a pixel separation section on a first surface of a semiconductor substrate and wiring layers in a multilayer wiring layer provided on a side of a first surface of the semiconductor substrate to each other. This reduces leaked light from adjacent pixels. It is therefore possible to suppress crosstalk.

(1)

A photodetector including:
a semiconductor substrate having a first surface and a second surface opposed to each other and including a pixel array section in which a plurality of pixels is arranged in array in an in-plane direction;
a light-receiving section provided inside the semiconductor substrate for each of the pixels and generating carriers corresponding to a received light amount by photoelectric conversion;
a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section;
a pixel separation section provided between the plurality of pixels adjacent to each other to extend from the first surface to the second surface of the semiconductor substrate, the pixel separation section electrically separating the plurality of adjacent pixels from each other;
a first contact layer provided around each of the plurality of pixels along the pixel separation section on the first surface of the semiconductor substrate and being electrically coupled to the light-receiving section;
a second contact layer provided on the first surface of the semiconductor substrate and being electrically coupled to the multiplication section; and
connection wiring that, in a multilayer wiring layer including one or a plurality of wiring layers provided on the side of the first surface of the semiconductor substrate, electrically couples the first contact layer and the one or the plurality of wiring layers to each other, the connection wiring being provided independently for each of the plurality of pixels.
   (2)

The photodetector according to (1), in which the connection wiring is formed along an outer shape of each of the pixels.

(3)

The photodetector according to (1) or (2), in which the connection wiring is formed continuously along the outer shape of each of the pixels.

(4)

The photodetector according to (1) or (2), in which the connection wiring is formed in a dotted manner along the outer shape of each of the pixels.

(5)

The photodetector according to (1) or (2), in which the connection wiring is formed in a meandering manner along the outer shape of each of the pixels.

(6)

The photodetector according to any one of (1) to (5), in which
the pixels each have a rectangular shape, and
the connection wiring is formed along the outer shape of each of the pixels, and has a shape of a rectangular frame body in a plan view.
   (7)

The photodetector according to (6), in which a corner of the connection wiring having the rectangular shape has an obtuse angle.

(8)

The photodetector according to any one of (1) to (3), in which
the pixels each have a rectangular shape, and
the connection wiring is provided along sides of each of the plurality of pixels adjacent to each other in a row direction and a column direction, in a plan view, except intersections of the plurality of pixels adjacent to each other in an oblique direction.
   (9)

The photodetector according to any one of (1) to (7), in which the connection wiring is provided in a staggered manner in the pixel array section in which the arrangement is made in array.

(10)

The photodetector according to any one of (1) to (7) and (8), in which the connection wiring is formed along the outer shape of each of the pixels, and has a shape of a circular frame body in a plan view.

(11)

The photodetector according to any one of (1) to (10), in which the connection wiring is provided on an inner side of each of the pixels than the pixel separation section in a plan view.

(12)

The photodetector according to any one of (1) to (11), in which the connection wiring is formed using tungsten, aluminum, copper, cobalt, nickel, or titanium, or a silicon compound thereof.

(13)

The photodetector according to any one of (1) to (12), in which the connection wiring is formed using polysilicon.

(14)

The photodetector according to any one of (1) to (13), in which
the first electrically-conductive region and the second electrically-conductive region are stacked in this order from the side of the first surface of the semiconductor substrate,
the first electrically-conductive region is partially provided substantially at a middle of each of the pixels, and
the second electrically-conductive region is provided across an entire surface of each of the pixels.
   (15)

A distance measurement apparatus including:
an optical system;
a photodetector; and
a signal processing circuit that calculates a distance to a measurement target from an output signal of the photodetector,
the photodetector including
   a semiconductor substrate having a first surface and a second surface opposed to each other and including a pixel array section in which a plurality of pixels is arranged in array in an in-plane direction,
   a light-receiving section provided inside the semiconductor substrate for each of the pixels and generating carriers corresponding to a received light amount by photoelectric conversion,
   a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section,
   a pixel separation section provided between the plurality of pixels adjacent to each other to extend from the first surface to the second surface of the semiconductor substrate, the pixel separation section electrically separating the plurality of adjacent pixels from each other,
   a first contact layer provided around each of the plurality of pixels along the pixel separation section on the first surface of the semiconductor substrate and being electrically coupled to the light-receiving section,
   a second contact layer provided on the first surface of the semiconductor substrate and being electrically coupled to the multiplication section, and
   connection wiring that, in a multilayer wiring layer including one or a plurality of wiring layers provided on the side of the first surface of the semiconductor substrate, electrically couples the first contact layer and the one or the plurality of wiring layers to each other, the connection wiring being provided independently for each of the plurality of pixels.
      (16)

A photodetector including:
a semiconductor substrate having a first surface and a second surface opposed to each other and including a pixel array section in which a plurality of pixels is arranged in array in an in-plane direction;
a light-receiving section provided inside the semiconductor substrate for each of the pixels and generating carriers corresponding to a received light amount by photoelectric conversion;
a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section;
a plurality of pixel separation sections extending from the first surface to the second surface of the semiconductor substrate and being provided independently for the respective plurality of pixels, the plurality of pixel separation sections electrically separating the plurality of adjacent pixels from each other;
a first contact layer provided in a first compartment of each of the plurality of pixels along the pixel separation sections on the first surface of the semiconductor substrate and being electrically coupled to the light-receiving section;
a second contact layer provided in a second compartment opposed, on a diagonal line, to the first compartment, the second contact layer being electrically coupled to the multiplication section, the first compartment being provided with the first contact layer of each of the plurality of pixels along the pixel separation sections on the first surface of the semiconductor substrate; and
connection wiring that, in a multilayer wiring layer including one or a plurality of wiring layers provided on the side of the first surface of the semiconductor substrate, is electrically coupled to the first contact layer or the second contact layer through the one or the plurality of wiring layers, the connection wiring being provided in a lattice pattern in a plan view by being provided between adjacent pixels.
   (17)

The photodetector according to (16), in which each of the plurality of pixel separation sections is provided inside the connection wiring provided in a lattice pattern in a plan view.

(18)

A photodetector including:
a semiconductor substrate having a first surface and a second surface opposed to each other and including a pixel array section in which a plurality of pixels is arranged in array in an in-plane direction;
a light-receiving section provided inside the semiconductor substrate for each of the pixels and generating carriers corresponding to a received light amount by photoelectric conversion;
a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section;
a pixel separation section provided between the plurality of pixels adjacent to each other to extend from the first surface to the second surface of the semiconductor substrate, the pixel separation section electrically separating the plurality of adjacent pixels from each other;
a first contact layer provided around each of the plurality of pixels along the pixel separation section on the first surface of the semiconductor substrate and being electrically coupled to the light-receiving section;
a second contact layer provided on the first surface of the semiconductor substrate and being electrically coupled to the multiplication section; and
connection wiring that, in a multilayer wiring layer including one or a plurality of wiring layers provided on the side of the first surface of the semiconductor substrate, is provided to straddle the pixel separation section and electrically couples the first contact layer provided in each of the plurality of adjacent pixels and the one or the plurality of wiring layers to each other.
   (19)

The photodetector according to (18), in which
the pixels each have a rectangular shape, and
the connection wiring is provided to overlap the pixel separation section, in a plan view, except intersections of the plurality of pixels adjacent to each other in an oblique direction.
   (20)

A photodetector including:
a semiconductor substrate having a first surface and a second surface opposed to each other and including a pixel array section in which a plurality of pixels is arranged in array in an in-plane direction;
a light-receiving section provided inside the semiconductor substrate for each of the pixels and generating carriers corresponding to a received light amount by photoelectric conversion;
a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section; and
a pixel separation section that is provided between the plurality of pixels adjacent to each other, extends from the first surface to the second surface of the semiconductor substrate, and electrically separates the plurality of adjacent pixels from each other, the pixel separation section reaching a wiring layer provided in a multilayer wiring layer provided on the side of the first surface of the semiconductor substrate.
   (21)

The photodetector according to (20), further including:
a first contact layer provided around each of the plurality of pixels along the pixel separation section on the first surface of the semiconductor substrate and being electrically coupled to the light-receiving section;
a second contact layer provided on the first surface of the semiconductor substrate and being electrically coupled to the multiplication section; and
connection wiring that, in the multilayer wiring layer including one or a plurality of wiring layers provided on the side of the first surface of the semiconductor substrate, is provided to straddle the pixel separation section and electrically couples the first contact layer provided in each of the plurality of adjacent pixels and the one or the plurality of wiring layers to each other, in which
the first contact layer and the second contact layer are each electrically coupled to the one or the plurality of wiring layers through the connection wiring provided in the multilayer wiring layer.

The present application claims the benefit of Japanese Priority Patent Application JP2022-089585 filed with the Japan Patent Office on Jun. 1, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A photodetector comprising:
a semiconductor substrate having a first surface and a second surface opposed to each other and including a pixel array section in which a plurality of pixels is arranged in array in an in-plane direction;
a light-receiving section provided inside the semiconductor substrate for each of the pixels and generating carriers corresponding to a received light amount by photoelectric conversion;
a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section;
a pixel separation section provided between the plurality of pixels adjacent to each other to extend from the first surface to the second surface of the semiconductor substrate, the pixel separation section electrically separating the plurality of adjacent pixels from each other;
a first contact layer provided around each of the plurality of pixels along the pixel separation section on the first surface of the semiconductor substrate and being electrically coupled to the light-receiving section;
a second contact layer provided on the first surface of the semiconductor substrate and being electrically coupled to the multiplication section; and
connection wiring that, in a multilayer wiring layer including one or a plurality of wiring layers provided on the side of the first surface of the semiconductor substrate, electrically couples the first contact layer and the one or the plurality of wiring layers to each other, the connection wiring being provided independently for each of the plurality of pixels.

2. The photodetector according to claim 1, wherein the connection wiring is formed along an outer shape of each of the pixels.

3. The photodetector according to claim 1, wherein the connection wiring is formed continuously along an outer shape of each of the pixels.

4. The photodetector according to claim 1, wherein the connection wiring is formed in a dotted manner along an outer shape of each of the pixels.

5. The photodetector according to claim 1, wherein the connection wiring is formed in a meandering manner along an outer shape of each of the pixels.

6. The photodetector according to claim 1, wherein
the pixels each have a rectangular shape, and
the connection wiring is formed along an outer shape of each of the pixels, and has a shape of a rectangular frame body in a plan view.

7. The photodetector according to claim 6, wherein a corner of the connection wiring having the rectangular shape has an obtuse angle.

8. The photodetector according to claim 1, wherein
the pixels each have a rectangular shape, and
the connection wiring is provided along sides of each of the plurality of pixels adjacent to each other in a row direction and a column direction, in a plan view, except intersections of the plurality of pixels adjacent to each other in an oblique direction.

9. The photodetector according to claim 1, wherein the connection wiring is provided in a staggered manner in the pixel array section in which the arrangement is made in array.

10. The photodetector according to claim 1, wherein the connection wiring is formed along an outer shape of each of the pixels, and has a shape of a circular frame body in a plan view.

11. The photodetector according to claim 1, wherein the connection wiring is provided on an inner side of each of the pixels than the pixel separation section in a plan view.

12. The photodetector according to claim 1, wherein the connection wiring is formed using tungsten, aluminum, copper, cobalt, nickel, or titanium, or a silicon compound thereof.

13. The photodetector according to claim 1, wherein the connection wiring is formed using polysilicon.

14. The photodetector according to claim 1, wherein
the first electrically-conductive region and the second electrically-conductive region are stacked in this order from the side of the first surface of the semiconductor substrate,
the first electrically-conductive region is partially provided substantially at a middle of each of the pixels, and
the second electrically-conductive region is provided across an entire surface of each of the pixels.

15. A distance measurement apparatus comprising:
an optical system;
a photodetector; and
a signal processing circuit that calculates a distance to a measurement target from an output signal of the photodetector,
the photodetector including
a semiconductor substrate having a first surface and a second surface opposed to each other and including a pixel array section in which a plurality of pixels is arranged in array in an in-plane direction,
a light-receiving section provided inside the semiconductor substrate for each of the pixels and generating carriers corresponding to a received light amount by photoelectric conversion,
a multiplication section including, for each of the pixels, a first electrically-conductive region and a second electrically-conductive region having an electrically-conductive type different from the first electrically-conductive region, the first electrically-conductive region and the second electrically-conductive region being stacked on a side of the first surface of the semiconductor substrate, the multiplication section performing avalanche multiplication of the carriers generated in the light-receiving section,
a pixel separation section provided between the plurality of pixels adjacent to each other to extend from the first surface to the second surface of the semiconductor substrate, the pixel separation section electrically separating the plurality of adjacent pixels from each other,
a first contact layer provided around each of the plurality of pixels along the pixel separation section on the first surface of the semiconductor substrate and being electrically coupled to the light-receiving section,
a second contact layer provided on the first surface of the semiconductor substrate and being electrically coupled to the multiplication section, and
connection wiring that, in a multilayer wiring layer including one or a plurality of wiring layers provided on the side of the first surface of the semiconductor substrate, electrically couples the first contact layer and the one or the plurality of wiring layers to each other, the connection wiring being provided independently for each of the plurality of pixels.
